(19) United States
(12) Patent Application Publication
(10) Pub. No.: US 2025/0286013 A1
(43) Pub. Date: Sep. 11, 2025

(54) APPARATUS AND METHOD FOR MANUFACTURING A POWER SEMICONDUCTOR DEVICE

(71) Applicant: ZF Friedrichshafen AG, Friedrichshafen (DE)

(72) Inventor: Fabian Hohmann, Hofbieber (DE)

(73) Assignee: ZF Friedrichshafen AG, Friedrichshafen (DE)

(21) Appl. No.: 19/071,428

(22) Filed: Mar. 5, 2025

(30) Foreign Application Priority Data
Mar. 5, 2024 (DE) 10 2024 202 012.5

(51) Int. Cl. H01L 23/00; H01L 23/538; H01L 25/07

(52) U.S. Cl. CPC H01L 24/75; H01L 23/5385; H01L 23/5386; H01L 24/32; H01L 24/83; H01L 25/072; H01L 2224/32225; H01L 2224/7555; H01L 2224/759; H01L 2224/8384; H01L 2224/83908; H01L 2924/401

(57) ABSTRACT

An apparatus for manufacturing a power semiconductor device with power semiconductors contacted on both sides has a receiver for a fundamental assembly that is to be sintered, which has a lower contact module, a power semiconductor, and sintering compound therebetween; a stamping unit that has a stamp for exerting a predefined pressure on the fundamental assembly to generate a sintered bond between the lower contact module and the power semiconductor; and a measuring device for determining the height of an upper surface of the power semiconductor above the lower contact module after the sintering. Also disclosed are a method for manufacturing a power semiconductor device with power semiconductors contacted on both sides, and a power semiconductor device.

### CROSS-REFERENCE TO RELATED APPLICATION

This application claims priority to German Patent Application No. 10 2024 202 012.5 filed on Mar. 5, 2024, the entirety of which is hereby fully incorporated by reference herein.

### TECHNICAL FIELD

The present disclosure relates to an apparatus for manufacturing a power semiconductor device with power semiconductors that are contacted from both sides. The present disclosure relates to a method and a power semiconductor device.

### BACKGROUND

The power electronics in electric and hybrid vehicles conducts the traction power from the battery to the electric motor, converting direct current into alternating current. This requires an AC converter, i.e. an inverter or traction inverter. Numerous transistors or power semiconductors are normally used for this, forming a power semiconductor module, which are switched on and off in short, regular intervals. In particular, metal-oxide-semiconductor field-effect transistors (MOSFETs) or insulated-gate bipolar transistors (IGBTs) are used for this. When switched on, current is conducted from the battery to the motor (conducting phase). As a result of this high-frequency switching, a voltage curve in the alternating current is obtained which can then be used in the electric motor as traction power. Numerous power semiconductors are usually connected in parallel in order to increase the ampacity.

Comparatively high currents are switched on and off with these power semiconductor modules, or power semiconductors, thus generating a lot of heat. Active or passive cooling systems are usually used to discharge the heat from the power semiconductors to another medium through a heat sink. These devices for inverters therefore contain contact modules in addition to the power semiconductors, with which electrical and thermal contact to the power semiconductors and cooling structures is obtained. This results in a heat-conducting path from the power semiconductors to a coolant. The heat-conducting path (thermal path) normally has electrically insulating layers (ceramic layers) that electrically insulate the cooling structure.

In the prior art, devices have been obtained in which individual power semiconductors have contacts for discharging heat on one or both sides.

A current approach in this context cools the power semiconductors from both sides to improve the cooling effect. A device, vehicle, method for the use thereof and a method for manufacturing the module are disclosed in DE 10 2016 121 801 A1. The device contains at least one electronic chip. It also contains at least one heat sink to which the at least one chip is bonded. The device also has a second heat sink to which the at least one chip is bonded. The device is also encased in a material that encases at least part of the at least one chip, part of the first heat sink, and part of the second heat sink. The first bond has a different melting temperature than the second.

A disadvantage with this is that manufacturing devices with contacts on both sides is usually complicated. Multi-step production processes are often more expensive and difficult. Differences in the sizes of the power semiconductors due to production tolerances also have special requirements.

### SUMMARY

Based on this, an object of the present disclosure is to create an efficient method for manufacturing power semiconductor devices with contacts on both sides. The size and design of these power semiconductor devices should be variable while still allowing them to be produced efficiently. There should also be fewer rejects.

These problems are solved in a first aspect of the present disclosure with an apparatus with which a power semiconductor device with power semiconductors contacted on both sides can be produced that has:
a receiver that accommodates a fundamental assembly that is to be sintered, which has a lower contact module, a power semiconductor, and a sintering compound between the two;
a stamping unit with a stamp that exerts a predefined pressure on this fundamental assembly to generate a sintered connection between the lower contact module and the power semiconductor; and
a measuring device to determine the height of the upper surface of the power semiconductor above the lower contact module after the sintering.

Another aspect of the present disclosure relates to a method for manufacturing a power semiconductor device with power semiconductors contacted on both sides comprising the following steps:
receiving a fundamental assembly that is to be sintered, which has a lower contact module, a power semiconductor, and a sintering compound between the two, in a receiver;
exerting a predefined pressure on the fundamental assembly with a stamp in a stamp unit to generate a sintered connection between the lower contact module and power semiconductor; and
determining the height of the upper surface of the power semiconductor above the lower contact module after the sintering process using a measuring device.

Lastly, one aspect of the present disclosure relates to a power semiconductor device that has numerous power semiconductors that are sintered to a lower contact module and an upper contact module, in which at least one spacer is placed between at least one power semiconductor and the upper contact module to compensate for differences in the heights of the power semiconductors, and the power semiconductor device is preferably manufactured using the above apparatus and/or the above method.

Preferred embodiments of the present disclosure are described herein. It is understood that the features described above and explained below can be used not only in the given combinations, but also in other combinations or in and of themselves, without abandoning the scope of the present disclosure. In particular, the apparatus, method, and power semiconductor device can be obtained in the embodiments described herein.

According to the present disclosure, a fundamental assembly for manufacturing a power semiconductor device with at least one power semiconductor contacted on both sides is first placed in a receiver. This fundamental assembly comprises a lower contact module on which the power semiconductor is placed with a sintering compound between the two. The pressure necessary for the sintering process is exerted by a stamp with which a sintered bond is obtained between the lower contact module and the power semiconductor. The stamp generates a predefined pressure that forms a processing parameter for the sintering process. After completion of the sintering process, the height of the upper surface of the power semiconductor above the lower contact module is measured by a measuring device. This basically defines the thickness of the power semiconductor and the sintered connection.

Flat power semiconductors (semiconductor chips) are used. These often have different heights, or thicknesses. In other words, they are often of different thicknesses. These different heights can present difficulties in obtaining contact on both sides. This may be the case in particular if numerous power semiconductors are placed on the same contact module or used for the same power semiconductor device. If power semiconductors of different thicknesses are used in the same device, for example, there must be some means of obtaining the same height in order to be able place an upper contact module thereon. A spacer can be used for this. Even if just one power semiconductor is used, it may be necessary to adjust the height to obtain an overall height in order to avoid exceeding or falling below a predefined maximum or minimum height. This is why the height of the upper surface of the power semiconductor above the lower contact module is determined.

Unlike with the prior art, a measuring device is used in the proposed apparatus for manufacturing a power semiconductor device to automatically determine the height of the upper surface of the power semiconductor above the lower contact module. This makes it possible to adjust the height during the production process, e.g. using spacers. Consequently, it is not difficult to determine the necessary size of the spacer. Compared to prior approaches, in which the size of the spacer is determined separately, this is more efficient. Compared to prior approaches in which a single power semiconductor is used in a power semiconductor device, a predefined height can be obtained, thus simplifying further processing of the power semiconductor device.

In a preferred design, the measuring device contains a laser for measuring the distance between the measuring device and the upper surface of the power semiconductor. This results in a precise measurement with reasonable costs. This also allows for a comprehensive measurement and mapping of different installation situations. The measurement is therefore precise and inexpensive.

In a preferred embodiment, the laser is configured to measure the depth of the stamping process. The laser is preferably parallel to the direction in which the stamp moves toward the surface on which it exerts pressure. In particular, it can be directed toward a measurement surface on the top of the stamp. If the length, or size, of the stamp is known, it is possible to determine how far the stamp presses downward. This relates directly to the height of the upper surface of the power semiconductor above the lower contact module as a result of the predefined pressure. This is applicable in particular if a consistent and known thickness of the lower contact module can be assumed. By using a measurement surface on the stamp when the laser is parallel to the direction of movement by the stamp, the measurement can be made simply and efficiently, with a low error rate.

In a preferred embodiment, the predefined pressure to the stamp exerted by the stamping unit is obtained with a pressurized medium, preferably air. This stamping unit is designed to pressurize a medium. This pressure is then applied to the stamp, such that it exerts a predefined pressure on the fundamental assembly that is to be sintered. The use of air allows for the measurement to be obtained by a laser that passes through the space filled therewith. In other words, the laser can be placed such that the interferometric measurement can be carried out within the pressure chamber. This results in an efficient measurement that can be easily implemented mechanically.

In a preferred embodiment, the stamping unit has a pressure chamber above the stamp for the medium. The measuring device is designed to take measurements inside the pressure chamber and is preferably above the pressure chamber. In other words, the measurement can take place inside the pressure chamber. It is particularly advantageous when a laser is placed inside the pressure chamber, and directed toward a measurement surface on the stamp, in particular on top of the stamp. By taking the measurement inside the pressure chamber, an efficient and precise measurement of the upper surface of the power semiconductor can be obtained. There is also very little risk of contamination affecting the precision of the measurement.

In a preferred embodiment, the measuring device contains an optical sensor for an optical code on the stamp, and is designed to determine the height on the basis of the optical code. The measuring device can also contain an ultrasound unit for measuring the distance and determining the height on the basis of this measurement. Instead of, or in addition to, the laser, an optical sensor can also be used. In particular, a camera can be used to read an optical code. This can then be used as the basis for determining the height. By way of example, the code can comprise a line or some other pattern, which can then be evaluated using image processing algorithms. Ultrasound measurements can also be used. Ultrasound measurement is also precise and inexpensive.

In a preferred embodiment, the receiver is designed to accommodate a fundamental assembly that is to be sintered, which has a lower contact module, two or more power semiconductors, and the sintering compound therebetween. The stamping unit contains a stamp for each power semiconductor, and is designed to exert the predefined pressure on each of the power semiconductors to generate a sintered bond in each case. The measuring device is designed to determine the heights of the upper surfaces of each of the power semiconductors above the contact module after the sintering. In particular, numerous power semiconductors can be placed on the same lower contact module in an advantageous embodiment of the apparatus obtained with the present disclosure. Ideally, a separate stamp is used for each power semiconductor, and the heights thereof are determined separately. These heights may differ from one power semiconductor to the next, depending on the thicknesses thereof. To compensate for this, or determine these differences, the measuring device is designed to determine the different heights of the upper surfaces thereof. This results in an efficient processing of the power semiconductor devices that have power semiconductors contacted on both sides.

In a preferred embodiment, the measuring device has a separate laser for measuring how far each of the stamps move downward. The measuring device could also have just one laser for measuring the movement of all of the stamps, which can be redirected for each stamp. The different measurements of the heights can be obtained with separate lasers, each of which is dedicated to a separate stamp. Alternatively, the individual measurements can be carried out sequentially with just one laser that can be redirected to each stamp. A mirror structure can be used to redirect the laser beam, such that only the mirrors therein need to be adjusted. This results in an efficient and inexpensive measurement process. This process is also precise.

In a preferred embodiment of the method obtained with the present disclosure, there is a step in which a spacer is placed on the fundamental assembly after the sintering process, which is attached with a second sintering process. The thickness of the spacer is based on the height of the upper surface of the power semiconductor that has been determined, such that a defined overall thickness of the fundamental assembly, with the spacer thereon, can be obtained. In particular, the spacer can be placed during the production process. This spacer is selected on the basis of the height of the upper surface of the power semiconductor, i.e. the thickness of the spacer is based thereon. By way of example, spacers from a predefined selection set can be used. It is also possible to create separate spacers, e.g. by applying a coating of an appropriate thickness using a plastic coating process. The placement of the spacer results in a defined overall thickness. This results in efficient further processing. It also reduces costs, because there is no need for a separate subsequent measurement.

In a preferred embodiment, the method contains a step in which an upper contact module is placed on the fundamental assembly, and a spacer is placed thereon in another sintering step. In particular, the upper contact module can be placed at the end of the process to obtain the defined height, such that no further adjustments are necessary. This results in an efficient production process for a power semiconductor device with power semiconductors that have contacts on both sides.

This power semiconductor device is understood to be a power semiconductor module or assembly for use in an inverter or inverter structure. There are normally numerous power semiconductors in a power semiconductor module, which in turn can contain numerous power semiconductor devices. A power semiconductor is an electronic chip (power semiconductor chip) that contains one or more integrated circuit components. MOSFETs or IGBTs can be used as power semiconductors, for example. Specifically, a power semiconductor is a semiconductor switch. The terms, “lower” and “upper” in reference to components or modules are used merely for clarification purposes. It is understood that the power semiconductor devices can also be inverted, or turned upside down. The same applies to distinctions between “first” and “second.” A first and second side, or first and second module, refer to different sides or modules. The power semiconductor device obtained with the present disclosure can be used in particular in a vehicle. Determination of a height refers to direct or indirect measurement of the thickness of a power semiconductor. This thickness may differ between power semiconductors due to production tolerances. This thickness is measured directly or indirectly, in order to be able to compensate for differences. This is of particular importance if numerous power semiconductors have to be contacted on both sides. This also has advantages with regard to further processing when there is only one power semiconductor.

The present disclosure shall be described and explained in greater detail below in reference to the drawings illustrating selected exemplary embodiments thereof.

### BRIEF DESCRIPTION OF THE DRAWINGS

FIG. 1 shows a schematic illustration of a vehicle with an inverter and a device obtained with the present disclosure;

FIG. 2 shows a schematic illustration of a thermal path from a semiconductor to a coolant in a device from the prior art;

FIG. 3 shows a schematic illustration of how different thicknesses of the power semiconductors can be problematic;

FIG. 4 shows a schematic illustration of an apparatus for manufacturing a power semiconductor device with power semiconductors contacted on both sides, without a measuring device;

FIG. 5 shows a schematic illustration of an apparatus for manufacturing a power semiconductor device with power semiconductors contacted on both sides;

FIG. 6 shows a schematic illustration of a power semiconductor device obtained with the present disclosure, with power semiconductors contacted on both sides, and with spacers;

FIG. 7 shows a schematic illustration of an alternative embodiment of an apparatus for manufacturing a power semiconductor device obtained with the present disclosure; and

FIG. 8 shows a schematic illustration of the method obtained with the present disclosure.

### DETAILED DESCRIPTION

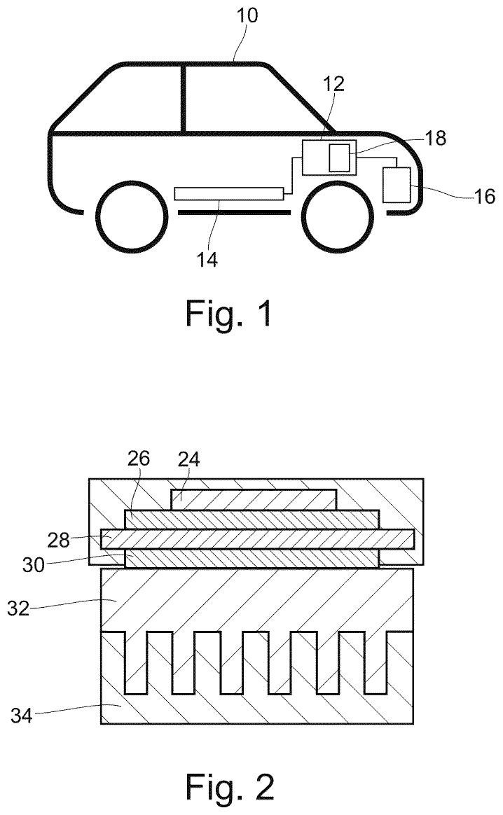

FIG. 1 shows a schematic illustration of a vehicle 10 that contains an inverter 12 obtained with the present disclosure. The inverter 12 is between a battery 14 and an electric machine 16 in the vehicle 10, to convert the direct current from the battery 14 into the alternating current needed for the electric machine 16. The inverter 12 contains numerous power semiconductor devices 18, which can be combined to obtain a power semiconductor module, wherein there can be numerous power semiconductor modules. The power semiconductor devices 18 each contain the power semiconductors or semiconductor switches, which can be MOSFETs, in particular. This illustration is understood to be schematic, and some components are not shown for purposes of clarity.

Current inverters are distinguished in that the semiconductor switches (power semiconductors) must be actively cooled to eliminate switching and performance losses. A thermal path from the semiconductor to a coolant is created to eliminate these losses. This thermal path contains the components shown in FIG. 2 in the devices from the prior art, for example.

In order to discharge the heat, the power semiconductor 24 is on an upper copper layer 26, which is on a ceramic layer 28 and a lower copper layer 30. The structure composed of the upper copper layer 26, lower copper layer 30, and ceramic layer 28 is also referred to as a direct bonded copper structure (DBC structure). The DBC structure is on a cooling plate 32 (cooling element) that is in contact with the coolant 34. The thermal path from the power semiconductors 24 to the coolant 34 is formed over the various components, in which the DBC structure forms an electrically insulating layer.

The thermal resistance, i.e. the combined thermal resistances of the individual components in FIG. 2, has a strong effect on the conductivity of the semiconductor. Instead of the meandering structure of the cooling plate 32 shown in FIG. 2, pin-fin structures can also be used.

To optimize the thermal path, the thermal resistance must be minimized. There are electrically necessary resistances at this point, e.g. insulating the ceramic layer 28, as well as resistances necessary regarding the production. Production resistances include the resistances of the copper layers 26, 30, which are necessary for the structure and connections, the thicknesses of which can be optimized for thermal conductivity. There is also the resistance necessary for the production in the cooling plate 32, which cannot be optimized ideally for thermal conductance due to production and assembly restrictions. There is also a resistance necessary for the production in the transition between the copper plate 32 and coolant 34, which is also greater than technically necessary due to production and assembly restrictions.

The connections between the various components, e.g. between the cooling plate and copper, and between the copper and power semiconductors, is increasingly obtained through sintering. Sintered bonds have a low thermal resistance and high cycling durability. Special tools are necessary for obtaining a sintered bond of a high quality, with which it is possible to compensate for differences in height. With current power semiconductor devices that have power semiconductors contacted on both sides, it is often necessary to form bonds by brazing, because of the need to adjust for differences in height.

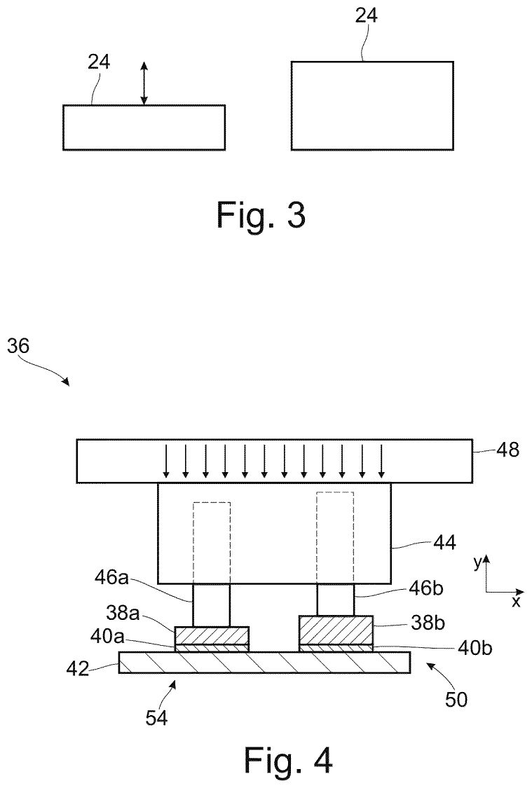

Two power semiconductors 24 of different thicknesses are shown in FIG. 3 (power semiconductors of different heights). Power semiconductors, or semiconductor chips, often have different thicknesses due to production tolerances. With sintered bonds, these differences must be compensated for. It is necessary to exert a nearly constant pressure on the tool to obtain a good sintered bond, despite these different thicknesses.

There are numerous ways of achieving this. A tool is necessary for compensating for these differences in height or thickness. FIG. 4 shows one possibility from the prior art. In particular, an apparatus 36 for manufacturing a power semiconductor device with power semiconductors that are contacted on both sides is shown. In this exemplary embodiment, a power semiconductor device is produced that has two power semiconductors 38a, 38b. The apparatus contains a stamping unit 44 with two stamps 46a, 46b that move along the vertical axis. The actual pressure is exerted by a liquid or gas that is introduced from the side of the apparatus 36. In particular, there is a pressure chamber 48 for this in this exemplary embodiment. Sintering compound 40a, 40b is applied at two points to a lower contact module 42. In this exemplary embodiment, the fundamental assembly 50 that is to be sintered comprises the lower contact module 42, the two power semiconductors 38a, 38b, and the sintering compound 40a, 40b. A receiver 54 accommodates the fundamental assembly 50.

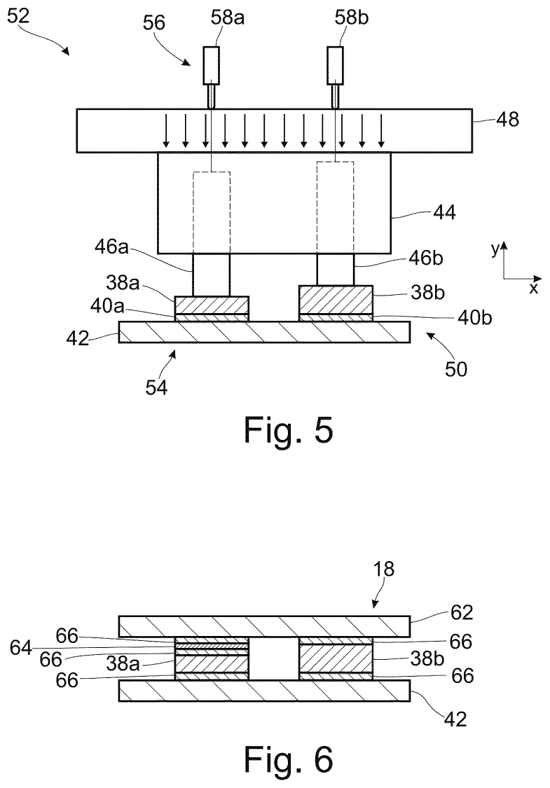

To implement such a sintering process for obtaining sintered bonds on both sides, in order to cool from both sides, the differences in height or thickness must be compensated for, preferably by a spacer. This requires a precise measurement of the difference in height. With the present disclosure, the height of the upper surface of the power semiconductors 38a, 38b above the lower contact module 42 after the sintering is determined. In this regard, FIG. 5 shows a schematic illustration of an embodiment of the apparatus 52 that is obtained with the present disclosure for manufacturing power semiconductor devices with power semiconductors contacted on both sides. This shows an embodiment with which a power semiconductor device with two power semiconductors 38a, 38b can be produced. The apparatus 52 can be a sintering press, or part thereof. The apparatus 52 contains a receiver 54 for a fundamental assembly 50 that is to be sintered. The fundamental assembly 50 comprises a lower contact module 52 and two power semiconductors 38a, 38b, which each have sintering compound 40a, 40b applied thereto in this exemplary embodiment. The apparatus 52 also has a stamping unit 44 with two stamps 46a, 46b, with which a predefined pressure can be exerted on the fundamental assembly 50 in order to obtain the sintered bonds. The stamping unit 44 in this exemplary embodiment has a pressure chamber 48 that contains a medium, in particular pressurized air, with which pressure can be exerted on the stamps 46a, 46b.

There is also a measuring device 56 that measures the height of the upper surfaces of both power semiconductors 38a, 38b above the lower contact module 42 after the sintering. In this exemplary embodiment, the measuring device 56 has two lasers 58a, 58b for measuring the distances from the measuring device 56 to the upper surfaces of the power semiconductors 38a, 38b. This shows that it is possible for the lasers to emit a laser beam into the pressure chamber 48 that strikes a measurement surface on the upper surfaces of the stamps 46a, 46b. In this regard, the measuring device is designed to take a measurement inside the pressure chamber 48. The two lasers 58a, 58b measure how far the stamps 46a, 46b move downward.

The present disclosure allows the heights, or differences in heights, to be determined precisely. These differences can then be compensated for in a subsequent sintering step for establishing contact to the power semiconductors 38a, 38b with an upper contact module (not shown). Because both stamps 46a, 46b are guided in the tool, deviations from the parallel can also be compensated for. The measurement is preferably carried out during the sintering process. The second sintering, for obtaining contact to the upper contact module, can take place directly thereafter.

It is understood that instead of the embodiment shown in FIG. 5, it is also possible to use power semiconductor devices with just one power semiconductor or with more than two power semiconductors. Accordingly, there may be a different number of stamps and/or lasers. It is also possible to measure numerous stamps with just one laser.

A power semiconductor device 18 is shown in FIG. 6 in this context that is produced using the apparatus described above. The power semiconductor device 18 in this exemplary embodiment comprises a lower contact module 42, two power semiconductors 38a, 38b, an upper contact module 62, and a spacer 64. There are sintered bonds 66 between each of the components.

Using the height measurement obtained with the present disclosure, a spacer can be inserted, e.g. on the upper surface of the power semiconductors, and bonded thereto in the sintering process. By this, a predefined maximum height can be obtained.

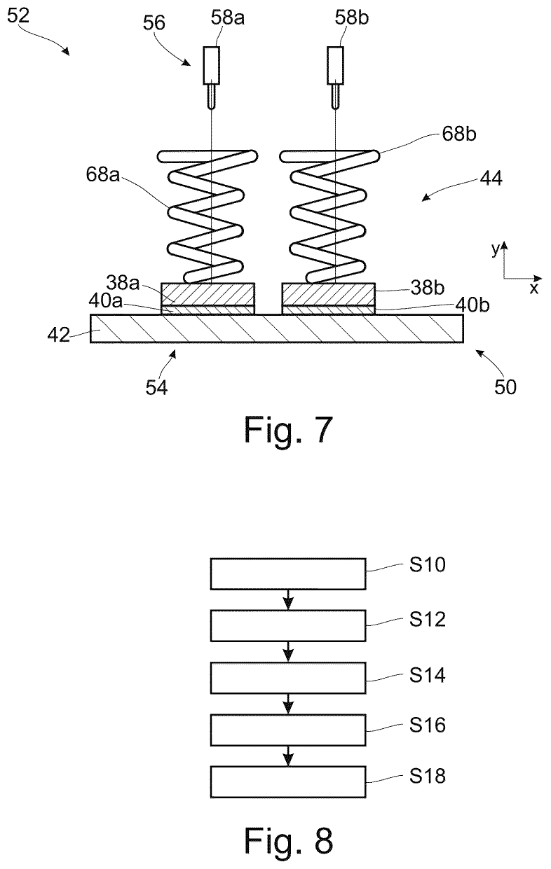

FIG. 7 shows a schematic illustration of an alternative embodiment of the apparatus 52 used in the present disclosure. With other sintering presses, compensation for vertical tolerances is obtained with springs (e.g. Belleville washers), which form the stamps in a stamping unit 44. It is also possible to measure heights through these springs, e.g. with lasers. The same reference symbols are used in FIG. 7 that are used in FIG. 5. The lasers 58a, 58b in the measuring device 56 are configured to measure the distance through the springs 68a, 68b.

Instead of using separate lasers for each stamp, a single laser can be used in another embodiment. This laser can be moved, for example, from one stamp to another. It is also possible to use other methods for measuring the distances, e.g. ultrasound or optical measurements. The method proposed herein can also be used for larger devices, e.g. when sintering entire modules.

FIG. 8 shows a schematic illustration of a method obtained with the present disclosure for manufacturing a power semiconductor device that has power semiconductors contacted from both sides. In step S10, a fundamental assembly that is to be sintered is obtained. In step S12, a predefined pressure is applied to the fundamental assembly. The height of the upper surface of the power semiconductor above the contact module is determined in step S14. In this exemplary embodiment, the method also contains an optional step S16 in which a spacer is placed on the fundamental assembly, and a step S18 in which an upper contact module is placed on the fundamental assembly. The method can be implemented with software that controls a production apparatus, for example. In particular, this method can be a method for manufacturing a power semiconductor device.

The present disclosure has been comprehensively described and explained in reference to the drawings. The descriptions and explanations are to be understood as exemplary, and not as limiting. The present disclosure is not limited to the disclosed embodiments. Other embodiments or variations can be derived by the person skilled in the art when using this present disclosure, or through a precise analysis of the drawings, the disclosure and the following claims.

The terms, “comprising” and “with,” in the claims do not exclude the presence of other elements or steps. The indefinite articles “a” and “an” do not exclude the presence of a plurality. A single element or unit can function as numerous units specified in the claims. An element, unit, interface, apparatus, or system can be implemented partially or entirely as hardware and/or software. Simply specifying certain measures in numerous dependent claims is not to be understood to mean that a combination of these measures cannot also be advantageously used. A computer program can be stored/executed on a non-volatile data storage medium, e.g. an optical memory or a solid-state drive (SSD). A computer program can be distributed along with hardware and/or as part of hardware, e.g. through the internet, or using hard-wired or wireless communication systems. The reference symbols in the claims are not to be understood as limiting.

### REFERENCE SYMBOLS

10 vehicle
12 inverter
14 battery
16 electric machine
18 power semiconductor device
24 power semiconductor
26 upper copper layer
28 ceramic layer
30 lower copper layer
32 cooling plate
34 cooling medium
36 apparatus from the prior art
38a, 38b power semiconductors
40a, 40b sintering compound
42 lower contact module
44 stamping unit
46a, 46b stamp
48 pressure chamber
50 fundamental assembly
52 apparatus
54 receiver
56 measuring device
58a, 58b lasers
62 upper contact module
64 spacer
66 sintering layer
68a, 68b springs

1. An apparatus for manufacturing a power semiconductor device with power semiconductors contacted on both sides, the apparatus comprising:
a receiver for a fundamental assembly that is to be sintered, which comprises a lower contact module, a power semiconductor, and sintering compound therebetween;
a stamping unit comprising a stamp configured to exert a predefined pressure on the fundamental assembly to generate a sintered bond between the lower contact module and the power semiconductor; and
a measuring device configured to determine a height of an upper surface of the power semiconductor above the lower contact module after the sintering.

2. The apparatus according to claim 1, wherein the measuring device comprises a laser configured to perform interferometric measurement of a distance between the measuring device and the upper surface of the power semiconductor.

3. The apparatus according to claim 2, wherein the laser is configured to measure a downward movement of the stamp, and is parallel to a direction the stamp moves toward a measurement surface on top of the stamp.

4. The apparatus according to claim 1, wherein the stamping unit is configured to exert the predefined pressure to the stamp with a pressurized medium.

5. The apparatus according to claim 4, wherein the stamping unit comprises a pressure chamber for the pressurized medium above the stamp, and wherein the measuring device is configured to take a measurement inside the pressure chamber, and is above the pressure chamber.

6. The apparatus according to claim 1, wherein the measuring device comprises an optical reader for an optical code on the stamp, and is configured to determine the height based on the optical code.

7. The apparatus according to claim 1, wherein the measuring device comprises an ultrasound unit configured to take an ultrasound measurement and to determine the height based on the ultrasound measurement.

8. The apparatus according to claim 1, wherein the receiver is configured to accommodate the fundamental assembly that comprises the lower contact module, two or more power semiconductors, and sintering compound between the lower contact module and the two or more power semiconductors,
wherein the stamping unit comprises a stamp for each power semiconductor of the two or more power semiconductors, and is configured to exert the predefined pressure on each power semiconductor to generate the sintered bond, and
wherein the measuring device is configured to determine heights of upper surfaces of the two or more power semiconductors above the contact module after the sintering.

9. The apparatus according to claim 8, wherein the measuring device comprises a plurality of lasers configured to measure a downward movement of each of the stamps, or a single laser configured to be redirected by moving it.

10. A method for manufacturing a power semiconductor device comprising power semiconductors that can be contacted on both sides, the method comprising:
receiving a fundamental assembly that is to be sintered, which has a lower contact module, a power semiconductor, and sintering compound between the lower contact module and the power semiconductor;
exerting a predefined pressure on the fundamental assembly to generate a sintered bond between the lower contact module and the power semiconductor using a stamp in a stamping unit; and
determining, with a measuring device, a height of an upper surface of the power semiconductor above the lower contact module after the sintering.

11. The method according to claim 10, comprising:
placing a spacer on the fundamental assembly after a sintering process by another sintering process, wherein a thickness of the spacer is determined on a basis of the height of the upper surface of the power semiconductor, in order to obtain a defined overall thickness of the fundamental assembly with the spacer thereon.

12. The method according to claim 11, comprising:
placing an upper contact module on the fundamental assembly and the spacer placed thereon.

13. A power semiconductor device comprising:
a plurality of power semiconductors that are secured between a lower contact module and an upper contact module with a sintered bond, wherein at least one spacer is placed between at least one of the power semiconductors and the upper contact module to compensate for height differences, wherein the power semiconductor device is produced using the method according to claim 10.
